(19) United States
(12) Patent Application Publication
(10) Pub. No.: US 2008/0005897 A1
(43) Pub. Date: Jan. 10, 2008

(54) Flexible wiring sheet, display apparatus and manufacturing method thereof

(75) Inventor: Futoshi Nakanishi, Kawasaki (JP)

Correspondence Address: YOUNG & THOMPSON, 745 SOUTH 23RD STREET, 2ND FLOOR, ARLINGTON, VA, 22202, US

(73) Assignee: NEC LCD TECHNOLOGIES, LTD., Kawasaki (JP)

(21) Appl. No.: 11/822,202

(22) Filed: Jul. 3, 2007

(30) Foreign Application Priority Data
Jul. 10, 2006 (JP) 2006-188952

(51) Int. Cl. H05K 3/00; H01L 23/02; H05K 1/00

(52) U.S. Cl. 29/829; 361/749; 257/678

(57) ABSTRACT

A flexible wiring sheet operable to electrically connect with an electronic apparatus includes a flexible sheet, a wiring line formed on the flexible sheet, an electric terminal which connects with the wiring line, the electric terminal being operable to electrically connects with the electronic apparatus, and an island-shaped resin which is formed in an area of the flexible sheet. The area of the flexible sheet overlaps with the electronic apparatus when the flexible sheet electrically connects with the electronic apparatus.

### RELATED APPLICATIONS

This application is based on Japanese Patent Application No. JP 2006-188952 filed on Jul. 10, 2006, and including a specification, claims, drawings and summary. The disclosure of the above Japanese Patent Application is incorporated herein by reference in its entirety.

### BACKGROUND OF THE INVENTION

1. Field of the Invention

The present invention relates to a flexible wiring sheet, an apparatus equipped with the flexible wiring sheet and a manufacturing method thereof and particularly, relates to a flexible wiring sheet to which an anisotropic conductive film is applied to connect an electric terminal, an apparatus equipped with the flexible wiring sheet and a manufacturing method thereof.

2. Description of Related Art

A display apparatus using a display panel such as a liquid crystal display panel and a plasma display panel is widely utilized. In the display apparatus, a flexible wiring sheet is usually used in order to electrically connect the display panel with an external circuit. Further, ACF (Anisotropic Conductive Film) is used widely to mount the flexible wiring sheet on the display panel of the display apparatus.

The ACF includes conductive particles and is made of resin for thermo-compression bonding. In case that the ACF is used for electrically connecting circuits, the ACF is interposed between substrates including circuits and thermo-compression bonding is conducted. As a result, the ACF electrically connect the circuits to be connected each other. Moreover, the substrates are joined together by the ACF. Since the ACF usually get hardened within a short period of time, e.g. not longer than several ten seconds, the ACF can rapidly connect the circuits including electric terminals. Accordingly, the ACF is frequently used for mass production of the display apparatus.

A liquid crystal display (LCD) module includes the flexible wiring sheet to which the ACF is applied. FIG. 7 shows an example of the LCD module. In a LCD module 1, a LCD panel 20a and a connecting substrate 30 are electrically connected to each other by a flexible wiring sheet 10c. An ACF is used for connection of the LCD panel 20a and the flexible wiring sheet 10c.

When the LCD module 1 is mounted on a case of a display apparatus, the external force is applied to the flexible wiring sheet 10c and the flexible wiring sheet 10c may be detached from the LCD panel 20a. A related art (Japanese Patent Application Laid-Open No. 1999-109397), discloses another configuration for adhesion.

FIG. 8 shows the configuration of a connection part of a LCD panel and a flexible wiring sheet according to the related art. In an LCD panel 20b, a pair of transparent substrates 21b and 21c made of glass or the like are joined together by a sealing member. Liquid crystal material is interposed between the transparent substrates 21b and 21c. A transistor is mounted on the LCD panel 20b. The transistor is covered with a plan layer (acrylic resin layer or the like). Electric terminals 231 are set in an area 23 of the transparent substrate 21b where the transparent substrate 21b does not overlap with the transparent substrate 21c. The electric terminals 231 are electrically connected with wiring drawn out from inside of a LCD panel 20b. A flexible wiring sheet 10d is joined to the electric terminals 231. On the flexible wiring sheet 10d, electric terminals 18e is arranged at a position corresponding to a position of the electric terminals 231. The electric terminals 231 and the electric terminals 18c are electrically connected by the ACF.

According to the related art, in order to prevent the flexible wiring sheet 10d from detaching from the LCD panel 20b, a resin for thermal-compression bonding is formed around the electric terminals 231 on the LCD panel 20b. When the LCD panel 20b is formed, the resin is formed through enlarging the plan layer which covers the transistor to a periphery region of the electric terminals 231. In the meanwhile, a resin for reinforcement is also formed on the flexible wiring sheet 10d. In FIG. 8, adhesion parts 51 and 52 are set at the both sides of the electric terminals 18c on the flexible wiring sheet 10d. An adhesive which can adhere to the plan layer is applied on the adhesion parts 51 and 52. At a temperature to fix the ACF firmly, the adhesive joins the adhesion parts 51 and 52 to the plan layer. Because another reinforced adhesion is provided to both of the LCD panel 20b and the flexible wiring sheet 10d, it can be suppressed that the flexible wiring sheet 10d detaches from the LCD panel 20b.

The reinforced adhesion means according to the related art has an advantage that the plan layer and the adhesion parts 51 and 52 can also adhere together simultaneously when performing thermal-compression bonding for the ACF. However, the above mentioned means has a problem in which it is hard to adjust a relative position of the LCD panel 20b to the flexible wiring sheet 10d.

In case of a mass production of the display module, the capability of the position adjustment has the significant influence on the production cost. When the relative position of the LCD panel 20b to the flexible wiring sheet 10d is found inappropriate after connecting them each other, the position adjustment is required. In the position adjustment process, the flexible wiring sheet 10d is detached from the LCD panel 20b and the relative position of the LCD panel 20b to the flexible wiring sheet 10d is adjusted and then, both of them are joined together again. In the position adjustment process, the ACF which is fixed with heat and stuck to the LCD panel 20b is removed by the solvent or the like and afterward, the LCD panel 20b needs to be cleaned. Moreover, it is necessary to form the resin film corresponding to the plan layer on the LCD panel 20b again.

It is difficult to secure the desired adhesion strength for adhering of the LCD panel 20b and the resin film only by applying the resin film to the LCD panel 20b and drying it. That is, the process in which the resin film is burned is needed after the application of the resin film. When the reinforced adhesion means according to the related art is used, it is difficult to adjust the position.

### SUMMARY OF THE INVENTION

The present invention was made to solve the foregoing and other exemplary problems, drawbacks, and disadvantages. The present invention provides a flexible wiring sheet, a display apparatus and manufacturing method thereof.

According to the present invention, an exemplary flexible wiring sheet operable to electrically connect with an electronic apparatus includes a flexible sheet, a wiring line formed on the flexible sheet, an electric terminal which connects with the wiring line, and an island-shaped resin. The electric terminal is operable to electrically connect with the electronic apparatus. The island-shaped resin which is formed in an area of the flexible sheet, the area of the flexible sheet is overlapping with the electronic apparatus when the flexible sheet electrically connects with the electronic apparatus.

According to the present invention, an exemplary method of manufacturing a flexible wiring sheet operable to electrically connect with an electronic apparatus includes forming a wiring line on a flexible sheet, forming at least one electric terminal which connects with the wiring line, and forming at least one island-shaped resin in an area of the flexible sheet, the flexible sheet overlapping with the electronic apparatus when the flexible sheet electrically connects with the electronic apparatus via the electric terminal.

According to the present invention, an exemplary electric apparatus includes a conductive part and a flexible wiring sheet. The flexible wiring sheet electrically connects with the conductive part via an anisotropy conductive resin film and includes a flexible sheet, a wiring line formed on the flexible sheet, and an island-shaped resin which is formed in an area of the flexible sheet. The area of the flexible sheet is overlapping with the electronic apparatus when the flexible sheet electrically connects with the electronic apparatus. The island-shaped resin adheres to the anisotropy conductive resin film.

According to the present invention, an exemplary assembling method of an electronic apparatus includes arranging an anisotropy conductive resin film in an area including an area of a predetermined conductive part of the electronic apparatus, arranging a flexible wiring sheet on the anisotropy conductive resin film so that an electric terminal formed on the flexible wiring sheet overlaps with the conductive part and an island-shaped resin formed on the flexible wiring sheet is positioned on the anisotropy conductive resin film, and heating and compressing the flexible wiring sheet on the anisotropy conductive resin film to join thereon.

Other exemplary features and advantages of the present invention will be apparent from the following description taken in conjunction with the accompanying drawings, in which like reference characters designate the same or similar parts throughout the figures thereof.

### BRIEF DESCRIPTION OF THE DRAWINGS

Exemplary features and advantages of the present invention will become apparent from the following detailed description when taken with the accompanying drawings in which:

FIG. 1 is a plan view of a flexible wiring sheet according to a first embodiment of the present invention;

FIG. 2 is a plan view showing that the flexible wiring sheet of FIG. 1 is mounted on an LCD panel;

FIG. 3A is a cross section when mounting the flexible wiring sheet of FIG. 1 on the LCD panel;

FIG. 3B is a cross section after mounting the flexible wiring sheet of FIG. 1 on the LCD panel;

FIG. 4 is a plan view showing that the flexible wiring sheet of FIG. 1 is mounted on the LCD panel;

FIG. 5 is a plan view of a flexible wiring sheet according to a second embodiment of the present invention;

FIG. 6 is a plan view of a flexible wiring sheet according to a third embodiment of the present invention;

FIG. 7 is a developed plan view of a LCD module according to a conventional example; and

FIG. 8 is a perspective view of a connection part of the flexible wiring sheet of the LCD module according to the pertinent art 1.

### DETAILED DESCRIPTION OF THE EXEMPLARY EMBODIMENTS

Exemplary embodiments of the present invention will now be described in detail in accordance with the accompanying drawings.

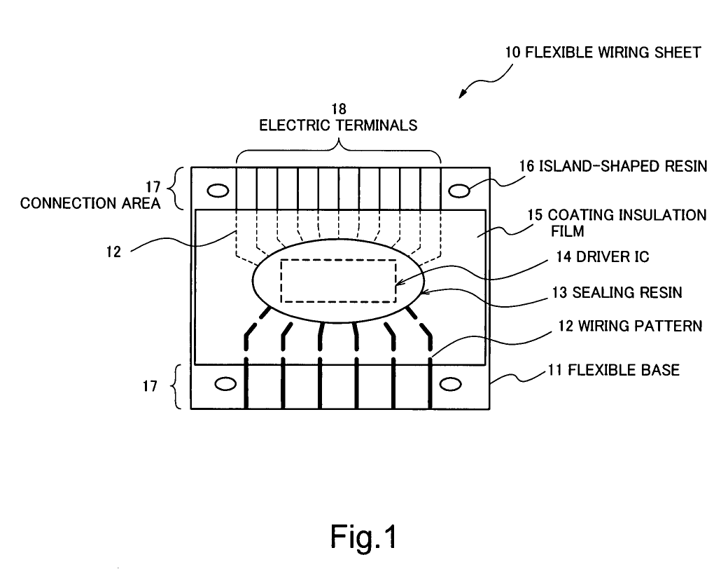

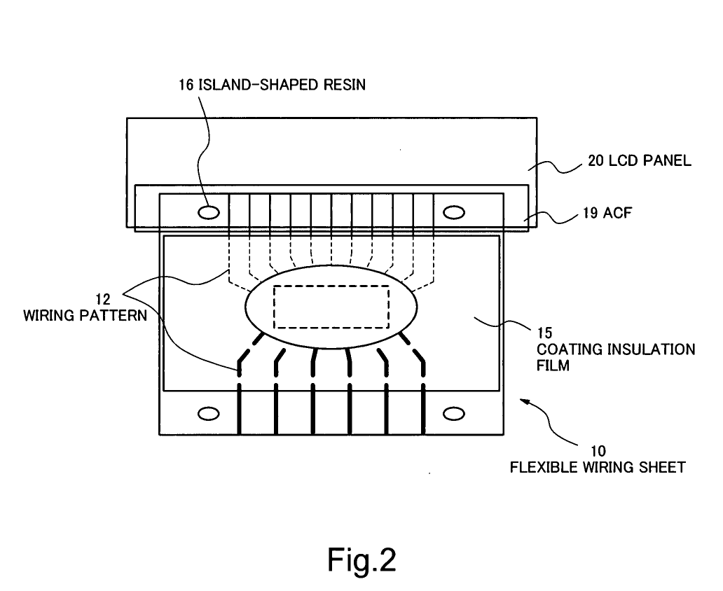

A first exemplary embodiment of the present invention will be described in the following. FIG. 1 shows a plan view of a flexible wiring sheet used for an LCD module according to the first exemplary embodiment. FIG. 2 shows a plan view illustrating that the flexible wiring sheet of FIG. 1 is mounted on a LCD panel. As shown in FIG. 1, a flexible wiring sheet 10 includes a flexible base 11 on which a driver IC 14 is mounted. The flexible base 11 is made of polyimide.

An edge area of the flexible base 11 is a connection area 17 for the flexible base 11 which joins other device such as the LCD panel. A plurality of electric terminals 18 is formed on the connection area 17. Island-shaped resin 16 is formed at both outsides of the electric terminals 18 on the connection area 17. The island-shaped resin 16 is formed by applying and curing insulating resin in shape of the island.

A connected wiring pattern 12 to be connected with the terminals 18 is formed in an area of the flexible base 11 except for the connection area 17. The wiring pattern 12 is covered with a coating insulation film 15 made of epoxy-based resin, urethane-based resin or the like. A driver IC 14 is mounted on the coating insulation film 15. The driver IC 14 is connected with the electric terminals 18 via the wiring pattern 12. The driver IC 14 is covered with an insulating sealing resin 13 in the first embodiment.

As shown in FIG. 2, the flexible wiring sheet 10 joins an LCD panel 20 which includes a glass substrate or the like via an ACF 19. When the flexible wiring sheet 10 and the LCD panel 20 are joined together via the ACF 19, an obstacle to flow of the ACF 19 should not be arranged within an area where the ACF 19 spreads. If the flow of the ACF 19 is disturbed, the conductive particles in the ACF 19 converge. Then, the conductive particles come in contact with each other. Consequently, desired electrical characteristics are not obtained any more. In order that the flow of the ACF 19 is not disturbed, the coating insulation film 15 is formed on an area where the coating insulation film 15 does not overlap with the LCD panel 20, that is, on an area except for the connection area 17.

It is desirable that the island-shaped resin 16 formed on the connection area 17 has a suitable size so that the flow of the ACF 19 may not be disturbed. Accordingly, the island-shaped resin 16 is formed in almost elliptic shape whose diameter in a direction of the long side of the electric terminal is shorter than the length of the electric terminal. Moreover, it is desirable that the diameter of the island-shaped resin 16 in the direction of the long side of the electric terminal should be shorter than a width of a thermo-compression bonding tool. For example, if the width of the thermo-compression bonding tool is about 1 mm, the diameter of the island-shaped resin 16 in the direction of the long side of the electric terminal is about 0.3 mm in width. A thickness of the island-shaped resin 16 is almost equal to a thickness of the coating insulation film 15. When the flexible wiring sheet 10 adheres to the LCD panel 20, the island-shaped resin 16 adheres to the ACF 19 simultaneously.

The island-shaped resin 16 can be formed through an application of a resin such as epoxy-based resin, urethane-based resin or the like according to a printing method or a potting method. In particular, it is desirable that the island shaped resin 16 is formed at the same time and with the same material as the coating insulation film 15 is formed, because an additional process is not necessary. When applying a thermosetting resin to the flexible base 11 and curing the thermosetting resin for not shorter than one hour, the thermosetting resin can adhere to the flexible base 11 with the high adhesion strength.

When the island-shaped resin 16 which adheres to the flexible base 11 with the high adhesion strength is joined to the ACF 19, the flexible wiring sheet 10 can be joined to the LCD panel 20 very firmly. In particular, if the island-shaped resin 16 is formed near the electric terminals 18, the electric connection between the terminals formed on the LCD panel 20 and the electric terminals 18 formed on the flexible wiring sheet 10 can be maintained well.

On the other hand, when it is founded that a relative position of the flexible wiring sheet 10 to the LCD panel 20 is wrong after the flexible wiring sheet 10 is connected to the LCD panel 20, the position adjustment is required. In the position adjustment process, the LCD panel 20 is detached from the flexible wiring sheet 10, and the LCD panel 20 has to be cleaned. As a result, the LCD panel 20 can be reused. Accordingly, a position adjustment is readily performed in case of mass production of the LCD module.

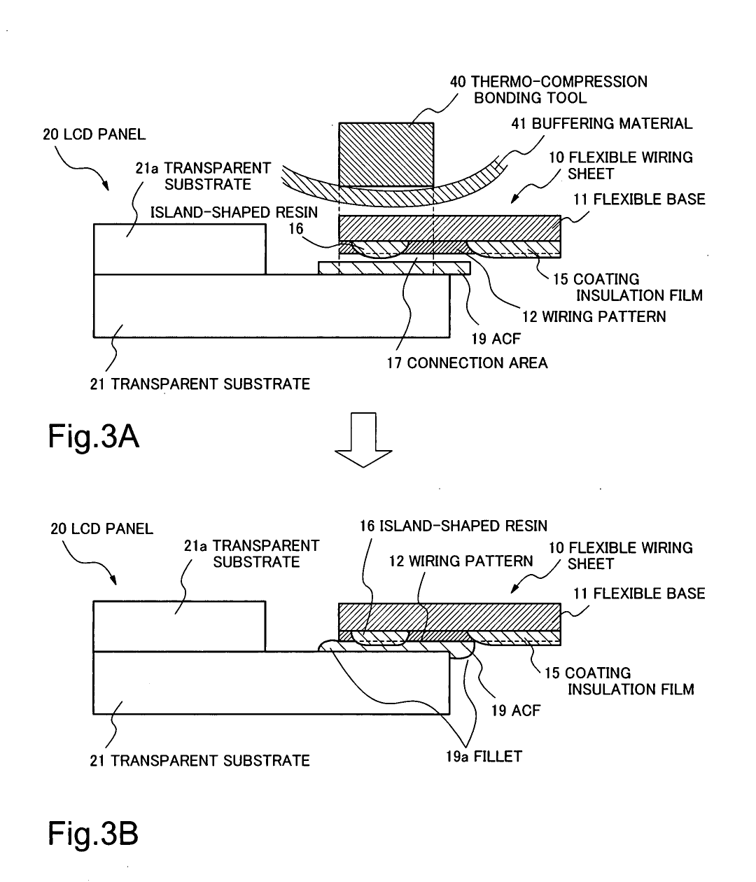

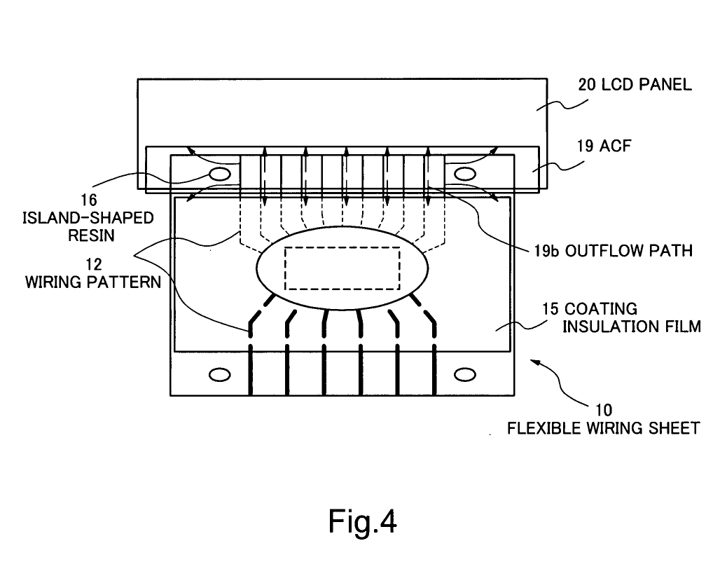

Next, a manufacturing process of a LCD module according to the first exemplary embodiment of the present invention will be described with reference to FIG. 3A, FIG. 3B and FIG. 4. FIG. 3A shows a process in which the flexible wiring sheet 10 is joined to the LCD panel 20. FIG. 3B shows a state in which the flexible wiring sheet 10 is mounted on the LCD panel 20. FIG. 4 is a perspective view from the back of the LCD module which includes the flexible wiring sheet 10 on the LCD panel 20.

First, an ACF 19 of a film type adheres to an area of the LCD panel 20 which overlaps with the flexible base 11. It is desirable that an size of the ACF 19 is slightly larger than the connection area 17 of the flexible base 11. The area to which the ACF 19 adheres extends right and left from the connection area 17 as shown in FIG. 3A.

After the ACF 19 adheres to the LCD panel 20, the flexible wiring sheet 10 is laminated on the ACF 19. At this time, the electric terminals 18 formed on the flexible base 11 overlap with the terminals formed on the LCD panel 20. As shown in FIG. 3A, a thermo-compression bonding tool 40 presses the flexible wiring sheet 10 via a buffering material 41 to cure the ACF 19. Then, the LCD panel 20 is joined to the flexible wiring sheet 10 via the ACF 19. At this time, the island-shaped resin 16 is cured simultaneously. And as shown in FIG. 3B, the island-shaped resin 16 becomes approximately plan and adheres to the ACF 19.

The coating insulation film 15 is formed in an area of the flexible base 11 apart from an area thereof where the LCD panel 20 overlaps. The island-shaped resin 16 is formed in the almost elliptic shape whose diameter in the direction of long side of the electric terminal is shorter than the length of the electric terminal among the electric terminals 18. Accordingly, the ACF 19 can flow over the side of the LCD panel 20 without being disturbed by the coating insulation film 15. The ACF 19 can spread over sufficiently without being disturbed by the island-shaped resin 16. FIG. 4 shows an outflow path 19b of the ACF 19. The ACF 19 which flows out forms a smooth shape (i.e. fillet) near the edge of the side of the LCD panel 20 and near the end portion of the flexible base 11. A fillet 19a is shown in FIG. 3B. When the fillet 19a is formed, the LCD panel 20 is firmly joined to the flexible wiring sheet 10.

As mentioned above, the island-shaped resin 16 is formed on the flexible wiring sheet 10 according to the first exemplary embodiment. When the LCD panel 20 is joined to the flexible wiring sheet 10 via the ACF 19, the island-shaped resin 16 is also joined to the ACF 19 simultaneously. By joining the island-shaped resin 16 formed on the flexible wiring sheet 10 to the ACF 19, joining of the LCD panel 20 and the flexible wiring sheet 10 can be reinforced. In particular, if the island-shaped resin 16 is formed near the electric terminals 18, the electric connection between the electric terminals formed on the LCD panel 20 and the electric terminals 18 formed on the flexible wiring sheet 10 can be maintained well.

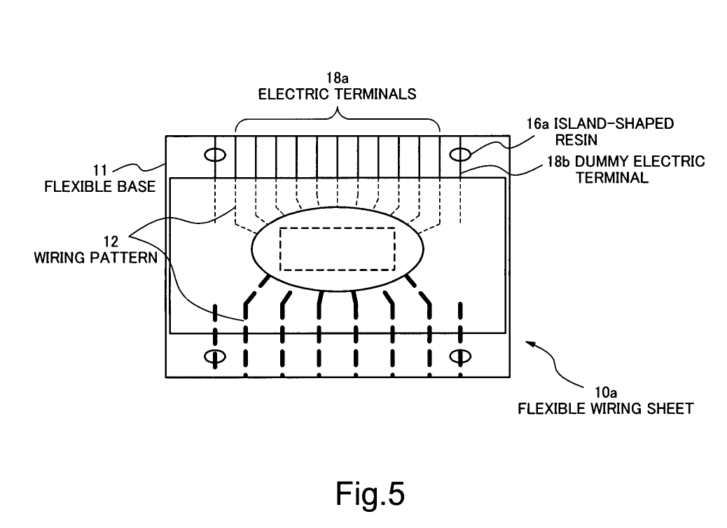

A second exemplary embodiment of the present invention will be described in the following. FIG. 5 shows a plan view of a flexible wiring sheet according to the second exemplary embodiment. The flexible base 11 is made of polyimide. A dummy electric terminal 18b is arranged outside electric terminals 18a on the flexible base 11, and is not connected with the wiring pattern 12. An island-shaped resin 16a is formed on the dummy electric terminal 18b.

In general, the adhesion strength of the thermosetting resin to the metal is stronger than that to the polyimide. When the island-shaped resin 16a is joined to the flexible base 11 via the dummy electrical terminal 18b, the dummy electric terminal 18b performs as an anchor. Thus, the island-shaped resin 16a can adhere to the flexible base 11 firmly. It is desirable that the dummy electric terminal 18b is formed simultaneously when the electric terminals 18a are formed on the flexible base 11.

In case of the second exemplary embodiment, time required for forming the island-shaped resin 16a on the flexible base 11 becomes short in comparison with the first exemplary embodiment.

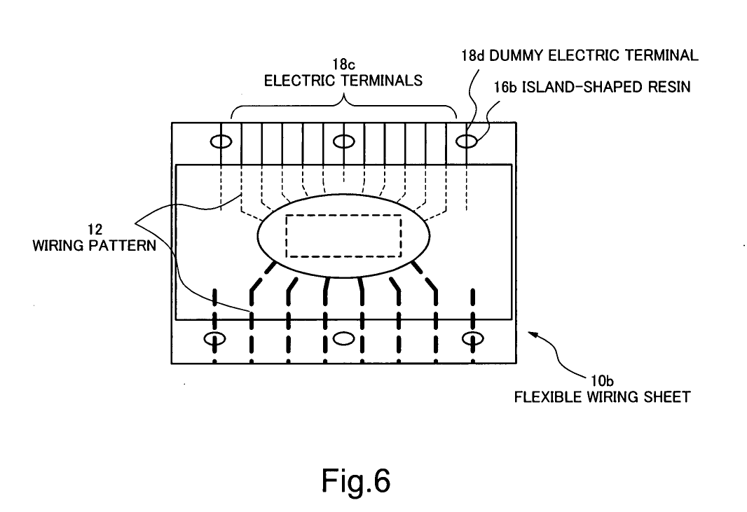

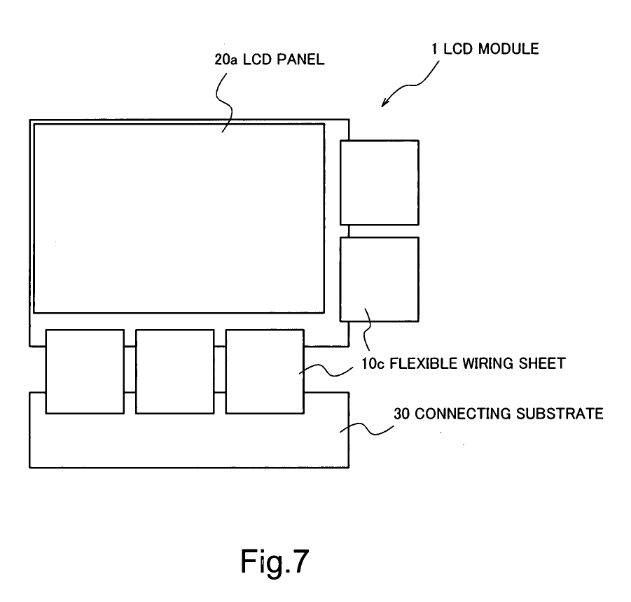

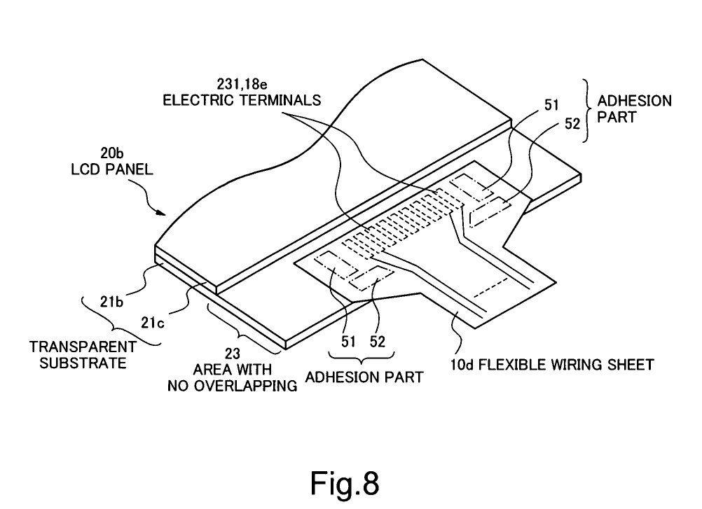

A third exemplary embodiment of the present invention will be described in the following. FIG. 6 shows a plan view of a flexible wiring sheet according to the embodiment. Dummy electric terminals 18d which are not connected with the wiring pattern 12 are also arranged between the electric terminals 18c and outside the electric terminals 18c as well. Island-shaped resins 16b are formed on the dummy electric terminals 18d. The dummy electric terminal 18d includes a material which has high adhesion strength to a thermosetting resin, and performs as an anchor for the island-shaped resins 16b. In such configuration, adhesion strength of a LCD panel to a flexible wiring sheet 10b becomes stronger than that of the above mentioned embodiments.

As mentioned above, the dummy electric terminal 18d is arranged not only outside the electric terminals 18c but also between the electric terminals 18c, and the island-shaped resins 16b are formed on the dummy electrical terminals 18d. Accordingly, the LCD panel 20 can be joined to the flexible wiring sheet 10b very firmly.

Here, the flexible wiring sheet 10 may be joined to the printed wiring board which processes the signals from the flexible wiring sheet 10, or the connecting board with a plurality of flexible wiring sheets. Moreover, structures according to the above-mentioned embodiments may be applied to structures for joining the various members together via the ACF 19.

The flexible wiring sheet and the display apparatus equipped with the flexible wiring sheet according to the present invention may be applied to a liquid crystal display apparatus for the flat panel or the like. Moreover, it may be applied to the display apparatus with the display panel such as a plasma display panel and an organic EL (electroluminescence) display panel.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments without the use of inventive faculty. Therefore, the present invention is not intended to be limited to the embodiments described herein but is to be accorded the widest scope as defined by the limitations of the claims and equivalents.

Further, it is noted that the inventor's intent is to retain all equivalents of the claimed invention even if the claims are amended during prosecution.

While this invention has been described in connection with certain preferred embodiments, it is to be understood that the subject matter encompassed by way of this invention is not to be limited to those specific embodiments. On the contrary, it is intended for the subject matter of the invention to include all alternative, modification and equivalents as can be included within the spirit and scope of the following claims.

Further, it is the inventor's intention to retain all equivalents of the claimed invention even if the claims are amended during prosecution.

What is claimed is:

1. A flexible wiring sheet operable to electrically connect with an electronic apparatus, comprising:
a flexible sheet;
a wiring line formed on the flexible sheet;
an electric terminal which connects with the wiring line, the electric terminal being operable to electrically connects with the electronic apparatus; and
an island-shaped resin which is formed in an area of the flexible sheet, the area of the flexible sheet overlapping with the electronic apparatus when the flexible sheet electrically connects with the electronic apparatus.

2. The flexible wiring sheet according to claim 1, wherein the electric terminal is formed an edge area of the flexible sheet.

3. The flexible wiring sheet according to claim 2, wherein the island-shaped resin is formed near the electric terminal.

4. The flexible wiring sheet according to claim 1, wherein the flexible wiring sheet includes at least one dummy electric terminal, and wherein the island-shaped resin is formed on the dummy electric terminal.

5. The flexible wiring sheet according to claim 1, wherein a part of the wiring line is covered with an insulating film.

6. The flexible wiring sheet according to claim 5, wherein the island-shaped resin and the insulating film are made of the same material.

7. The flexible wiring sheet according to claim 1, wherein the island-shaped resin is made of either of epoxy-based resin or urethane-based resin.

8. The flexible wiring sheet according to claim 7, wherein the island-shaped resin is formed according to either of a printing method or a potting method.

9. The flexible wiring sheet according to claim 1, wherein the island-shaped resin is elliptic in shape.

10. The flexible wiring sheet according to claim 1, wherein the island-shaped resin is circular in shape.

11. The flexible wiring sheet according to claim 1, wherein the flexible wiring sheet includes an electronic component which electrically connects with the wiring line.

12. The flexible wiring sheet according to claim 1, wherein the electric terminal is connected electrically with the electronic apparatus via an anisotropy conductive resin film.

13. The flexible wiring sheet according to claim 1, wherein the electric terminal is a part of the wiring line including an end portion of the wiring line.

14. A method of manufacturing a flexible wiring sheet operable to electrically connect with an electronic apparatus, comprising:
forming a wiring line on a flexible sheet;
forming at least one electric terminal which connects with the wiring line; and
forming at least one island-shaped resin in an area of the flexible sheet, the flexible sheet overlapping with the electronic apparatus when the flexible sheet electrically connects with the electronic apparatus via the electric terminal.

15. The method of manufacturing the flexible wiring sheet according to claim 14, wherein
forming at least one electric terminal comprises forming a dummy electric terminal, and wherein
forming at least one island-shaped resin comprises forming the island-shaped resin on the dummy electric terminal.

16. The method of manufacturing the flexible wiring sheet according to claim 14, further comprising:
forming an insulating film on a part of the wiring line.

17. The manufacturing method according to claim 16, wherein the insulating film is formed while the island-shaped resin is formed.

18. The method of manufacturing the flexible wiring sheet according to claim 14, further comprising:
mounting an electronic component on the flexible wiring sheet.

19. The method of manufacturing the flexible wiring sheet according to claim 14, further comprising:
electrically connecting the electric terminal and the electronic apparatus via an anisotropy conductive resin film.

20. An electronic apparatus, comprising:
a conductive part;
a flexible wiring sheet which electrically connects with the conductive part via an anisotropy conductive resin film; wherein the flexible wiring sheet including:
a flexible sheet;
a wiring line formed on the flexible sheet; and
an island-shaped resin which is formed in an area of the flexible sheet, the area of the flexible sheet overlapping with the electronic apparatus when the flexible sheet electrically connects with the electronic apparatus, and wherein the island-shaped resin adheres to the anisotropy conductive resin film.

21. The electronic apparatus according to claim 20, wherein the anisotropic conductive film joins the electronic apparatus and the flexible sheet.

22. The electronic apparatus according to claim 20, wherein a part of the wiring line is covered with an insulating film.

23. The electronic apparatus according to claim 20, wherein an electronic component is mounted on the flexible wiring sheet, the electronic component electrically connecting with the wiring line.

24. The electronic apparatus according to claim 20, wherein the island-shaped resin is formed on a dummy electric terminal of the flexible sheet.

25. The electronic apparatus according to claim 20, wherein the electronic apparatus is a liquid crystal display apparatus.

26. The electronic apparatus according to claim 20, wherein the electronic apparatus is a plasma display apparatus.

27. The electronic apparatus according to claim 20, wherein the electronic apparatus is an organic electroluminescence display apparatus.

28. An assembling method of an electronic apparatus, comprising:
arranging an anisotropy conductive resin film in an area including an area of a predetermined conductive part of the electronic apparatus;
arranging a flexible wiring sheet on the anisotropy conductive resin film so that an electric terminal formed on the flexible wiring sheet overlaps with the conductive part and an island-shaped resin formed on the flexible wiring sheet is positioned on the anisotropy conductive resin film; and
heating and compressing the flexible wiring sheet on the anisotropy conductive resin film to join thereon.
